(19) United States
(12) Patent Application Publication
(10) Pub. No.: US 2026/0026268 A1
(43) Pub. Date: Jan. 22, 2026

(54) SEMICONDUCTOR DEVICE INCLUDING RESISTANCE CHANGE LAYER AND THERMAL CONFINEMENT ELECTRODE LAYER

(71) Applicant: SK hynix Inc., Icheon-si (KR)

(72) Inventors: Sang Min LEE, Icheon-si (KR); Ka Young KIM, Icheon-si (KR); Sang Su PARK, Icheon-si (KR); Jae Yun YI, Icheon-si (KR)

(21) Appl. No.: 19/026,002

(22) Filed: Jan. 16, 2025

Related U.S. Application Data
(63) Continuation-in-part of application No. 18/908,390, filed on Oct. 7, 2024.

(30) Foreign Application Priority Data
Jul. 16, 2024 (KR) 10-2024-0094042

(51) Int. Cl. H10N 70/00; H10B 63/00; H10N 70/20

(52) U.S. Cl. CPC H10N 70/8413; H10B 63/30; H10B 63/80; H10N 70/24; H10N 70/8616; H10N 70/8833

(57) ABSTRACT

A semiconductor device includes a substrate, an electrode structure disposed over the substrate and including interlayer insulation layers and horizontal electrode layers which are alternately disposed, a resistance change layer disposed along a sidewall surface of a hole that penetrates the electrode structure on the substrate, an oxygen vacancy reservoir layer disposed on the resistance change layer within the hole, a first thermal confinement electrode layer disposed on the oxygen vacancy reservoir layer within the hole, and a vertical electrode layer disposed on the first thermal confinement electrode layer within the hole.

### CROSS-REFERENCE TO RELATED APPLICATION

The present application is a continuation in part of pending U.S. patent application Ser. No. 18/908,390, filed on Oct. 7, 2024, and claims priority under 35 U.S.C. § 119(a) to Korean Application No. 10-2024-0094042, filed in the Korean Intellectual Property Office on Jul. 16, 2024, which is incorporated herein by reference in its entirety.

### BACKGROUND

### 1. Technical Field

The present disclosure generally relates to a semiconductor device including a resistance change layer.

### 2. Related Art

In general, a resistance change material refers to a material whose electrical resistance changes when an external stimulus such as heat, current, voltage, or light is applied. The resistance change material can maintain its altered electrical resistance even after the external stimulus is removed. A product that utilizes the electrical characteristics of a resistance change material to store signal information is a resistance change memory device.

In a resistance change memory device, the resistance state of a memory layer can switch between a low resistance state and a high resistance state through a set operation and a reset operation. Depending on the factor causing the switching operation, the resistance change memory device can be classified into a resistive memory (Resistive RAM), a phase change memory (Phase Change RAM), a magnetic memory (Magnetic RAM), etc. In some resistance change memory devices, a filament-based resistive memory (Resistive RAM) can implement different resistance states by generating or disconnecting conductive filaments, which provide low resistance within a resistive switching layer when voltage or current is applied to both ends of the resistive switching layer. Recently, a technology for storing multiple levels of signal information by implementing multiple resistance states within a resistance change layer has been studied. Discussions about this technology include the possibility of applying the technology for storing multiple levels of signal information in a cell structure for analog calculations in neuromorphic devices.

### STATEMENT REGARDING PRIOR DISCLOSURES BY THE INVENTOR OR A JOINT INVENTOR

At least one inventor or joint inventor of the present disclosure has made related disclosures in 2023 International Electron Device Meeting (IEDM) at IEEE on Dec. 9, 2023.

### SUMMARY

A semiconductor device according to an embodiment of the present disclosure may include a substrate, an electrode structure disposed over the substrate and including interlayer insulation layers and horizontal electrode layers which are alternately disposed, a resistance change layer disposed along a sidewall surface of a hole that penetrates the electrode structure on the substrate, an oxygen vacancy reservoir layer disposed on the resistance change layer within the hole, a first thermal confinement electrode layer disposed on the oxygen vacancy reservoir layer within the hole, and a vertical electrode layer disposed on the first thermal confinement electrode layer within the hole.

A semiconductor device according to an embodiment of the present disclosure may include a first conductive line and a second conductive line that are disposed on different planes, and a device structure disposed in a region where the first conductive line and the second conductive line intersect. The device structure may include a resistance change layer, an oxygen vacancy reservoir layer, and a first thermal confinement electrode layer that are sequentially disposed between the first conductive line and the second conductive line.

### BRIEF DESCRIPTION OF THE DRAWINGS

FIG. 1 is a schematic cross-sectional view illustrating a semiconductor device according to an embodiment of the present disclosure.

FIG. 2A and FIG. 2B are schematic cross-sectional views illustrating a resistance change layer according to an embodiment of the present disclosure.

FIG. 3 is a schematic view illustrating the flow of internal heat during operation of a semiconductor device according to an embodiment of the present disclosure.

FIG. 4 is a schematic cross-sectional view illustrating a semiconductor device according to another embodiment of the present disclosure.

FIG. 5 is a schematic cross-sectional view illustrating a semiconductor device according to another embodiment of the present disclosure.

FIG. 6 is a schematic cross-sectional view illustrating a semiconductor device according to another embodiment of the present disclosure.

FIG. 7 is a schematic perspective view illustrating a semiconductor device according to another embodiment of the present disclosure.

FIG. 8 is a schematic cross-sectional view illustrating the semiconductor device of FIG. 7 taken along a line I-I′.

FIG. 9 is an enlarged view of a region “CR” in the cross-sectional view of FIG. 8.

FIG. 10 is a schematic view illustrating a flow of internal heat during an operation of a semiconductor device according to another embodiment of the present disclosure.

FIG. 11 is a schematic cross-sectional view illustrating a semiconductor device according to another embodiment of the present disclosure.

FIG. 12 is a schematic cross-sectional view illustrating the semiconductor device of FIG. 11 taken along a line II-II′.

FIG. 13 is a schematic perspective view illustrating a semiconductor device according to another embodiment of the present disclosure.

FIG. 14 to FIG. 17 are schematic perspective views illustrating device structures of a semiconductor device according to various embodiments of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or customs of a user or operator in the technical field. The meanings of the terms used follow the definitions defined when specifically defined herein, and may be interpreted as meanings generally recognized by those skilled in the art in the absence of specific definitions.

Semiconductor devices according to embodiments of the present disclosure include a resistance change layer disposed between a pair of electrodes. The resistance change layer can store multiple conductance values (or electrical resistances) that can be distinguished from each other. Additionally, the semiconductor devices include a thermal confinement electrode layer that mitigates the release of heat generated during device operation as the heat is released to the outside of the semiconductor device. The thermal confinement electrode layer has a lower thermal conductivity than an adjacent electrode, thereby helping to keep the heat generated during the set operation and reset operation of the semiconductor device inside of the semiconductor device.

The semiconductor devices according to embodiments of the present disclosure can be applied to analog computing in memory (hereinafter, referred to as “ACIM”). As an example, the semiconductor devices can be used in cells of a cell array device that stores consecutive weights and performs a vector matrix multiplication. That is, the semiconductor devices can be utilized as a memristor-based synaptic element in devices implementing neuromorphic technology.

In a published paper (“A Holistic Methodology Toward Large-scale AI Implementation using Realistic ReRAM based ACIM from Cell to Architecture, 2023 International Electron Devices Meeting (IEDM), 9-13 Dec. 2023”, hereinafter the “Paper”), the inventor of the present disclosure disclosed a configuration of a resistive RAM device having a thermal enhanced layer. The configuration of the resistive RAM device and the AciM based on the resistive memory device disclosed in the Paper, and the Paper itself, are incorporated by reference as though fully set forth herein.

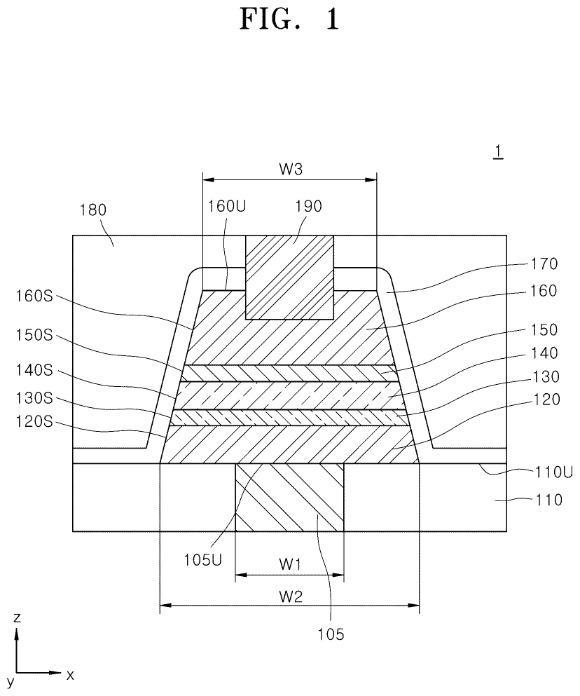

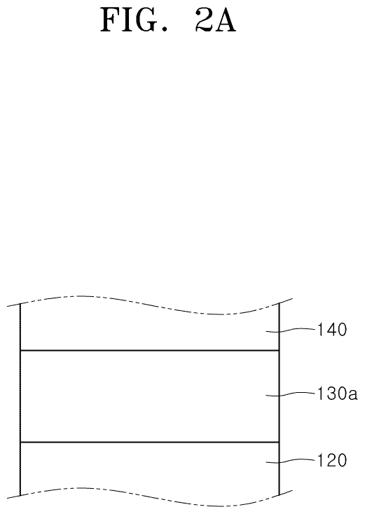

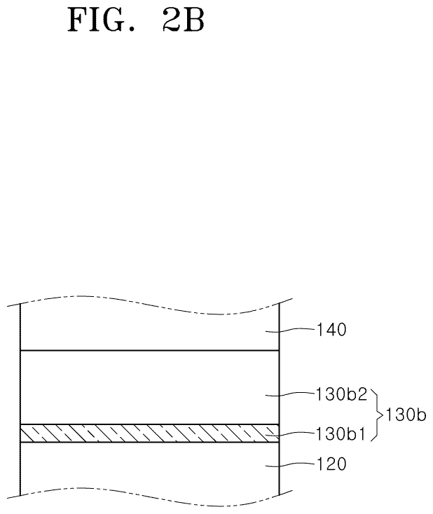

FIG. 1 is a schematic cross-sectional view illustrating a semiconductor device according to an embodiment of the present disclosure. FIG. 2A and FIG. 2B are schematic cross-sectional views illustrating a resistance change layer according to an embodiment of the present disclosure.

Referring to FIG. 1, a semiconductor device 1 includes a first electrode 120, a resistance change layer 130 disposed on the first electrode 120, an oxygen vacancy reservoir layer 140 disposed on the resistance change layer 130, a thermal confinement electrode layer 150 disposed on the oxygen vacancy reservoir layer 140, and a second electrode 160 disposed on the thermal confinement electrode layer 150. In addition, the semiconductor device 1 includes a contact plug electrode 105 and a contact electrode 190 that are electrically connected to the first electrode 120 and the second electrode 160, respectively.

The semiconductor device 1 may be disposed over a substrate (not shown). The substrate may include an insulating material, a conductive material, or a semiconductor material in which a semiconductor integration process can proceed. In an embodiment, the substrate may be a silicon substrate doped with an n-type or p-type dopant.

Referring to FIG. 1, the semiconductor device 1 includes the contact plug electrode 105 disposed over the substrate. The contact plug electrode 105 is electrically connected to the substrate and the first electrode 120. The contact plug electrode 105 may include, for example, metal, metal nitride, metal silicide, or a combination of two or more thereof. The contact plug electrode 105 is disposed to be surrounded by a base insulation layer 110 in a lateral direction (for example, x-direction or y-direction). The base insulation layer 110 may include, for example, oxide, nitride, oxynitride, or a combination two or more thereof. An upper surface 110U of the base insulation layer 110 may be substantially flat and may be positioned at substantially the same level as an upper surface 105U of the contact plug electrode 105.

In an embodiment, a selection transistor may be disposed over the substrate. The selection transistor may include a source electrode, a gate electrode, and a drain electrode. The source electrode may be electrically connected to a source line providing an operation voltage or a ground voltage, and the drain electrode may be electrically connected to the contact plug electrode 105. When the selection transistor is turned on, the source line may be electrically connected to the contact plug electrode 105 via a conductive channel formed under the gate electrode. In another embodiment, the selection transistor is excluded, and the source line may be directly connected to the contact plug electrode 105. As an example, the source line may be disposed over the substrate, and the contact plug electrode 105 may be disposed on the source line. The contact plug electrode 105 may include a conductive material. The conductive material may include, for example, metal, conductive metal nitride, conductive metal silicide, or a combination of two or more thereof.

Referring to FIG. 1, the first electrode 120 is disposed on the contact plug electrode 105 and the base insulation layer 110. The first electrode 120 is disposed to overlap with the contact plug electrode 105 in the z-direction. The first electrode 120 is disposed to cover the contact plug electrode 105. In one lateral direction (for example, x-direction), a width W2 of the first electrode 120 may be larger than a width W1 of the contact plug electrode 105.

The first electrode 120 may include a conductive material. The conductive material may include, for example, metal, conductive metal nitride, conductive metal carbide, conductive metal silicide, or conductive metal oxide. The conductive material may include, for example, platinum (Pt), gold (Au), tantalum (Ta), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The resistance change layer 130 is disposed on the first electrode 120. The resistance change layer 130 may include a resistance change material whose conductance (or electrical resistance) changes depending on an applied voltage or applied current. In addition, the resistance change material may maintain the changed conductance (or the changed electrical resistance) in a non-volatile manner after the applied voltage or applied current is removed.

In an embodiment, the resistance change layer 130 stores a plurality of distinct conductance values as signal information. As an example, the plurality of conductance values have a relationship in which the magnitude of the conductance values changes substantially linearly in relation to the magnitude of the applied operation voltage. The magnitude of the applied operation voltage may be controlled, for example, by the amplitude of a direct current (DC) voltage, the width of a pulse voltage, or the number of times the pulse voltage is applied.

In an embodiment, the resistance change material of the resistance change layer 130 may include oxygen vacancies. The resistance change material may include metal oxide that does not satisfy a stoichiometric ratio. The resistance change material may include, for example, hafnium oxide, zirconium oxide, hafnium zirconium oxide, titanium oxide, aluminum oxide, or a combination of two or more thereof.

The oxygen vacancies may operate as follows during a set operation or reset operation of the semiconductor device 1. For example, when a set voltage for a set operation is applied between the first electrode 120 and the second electrode 160, an electric field is formed in the resistance change layer 130 due to the set voltage. Oxygen vacancies aggregate along the electric field so that conductive filaments are formed in the thickness direction (that is, z-direction) of the resistance change layer 130. The conductive filaments may increase the conductance of the resistance change layer 130 by providing a path for conductive carriers to move in the z-direction through the resistance change layer 130. The width and distribution of the conductive filaments may vary depending on the magnitude of the applied set voltage. The conductance of the resistance change layer 130 may increase in proportion to the width and density of the conductive filaments. In another example, when a reset voltage for the reset operation is applied between the first electrode 120 and the second electrode 160, oxygen vacancies are separated from previously formed conductive filaments, and accordingly, the conductive filaments degrade and are electrically disconnected. The polarity of the reset voltage may be opposite to the polarity of the set voltage. By disconnecting the conductive filaments, the conductance of the resistance change layer 130 may decrease.

The resistance change layer 130 may have a single-layer or multi-layer structure. As an example of the resistance change layer 130 of FIG. 1, FIG. 2A and FIG. 2B schematically illustrate structures of resistance change layers 130a and 130b disposed between the first electrode 120 and the oxygen vacancy reservoir layer 140.

Referring to FIG. 2A, a resistance change layer 130a has a single layer structure. The resistance change layer 130a has a thickness that ranges from 10 Å (angstroms) through 100 Å. The resistance change layer 130a may include, for example, hafnium oxide, zirconium oxide, hafnium zirconium oxide, or a combination of two or more thereof.

Referring to FIG. 2B, a resistance change layer 130b includes

a first layer 130b1 and a second layer 130b2. The first layer 130b1 is disposed to contact the first electrode 120, and the second layer 130b2 is disposed on the first layer 130b1. The first layer 130b1 may include aluminum oxide. The first layer 130b1 has a thickness within a range of 2 Å through 10 Å. The second layer 130b2 may include, for example, hafnium oxide, zirconium oxide, hafnium zirconium oxide, or a combination of two or more thereof. The second layer 130b2 has a thickness within a range of 10 Å through 100 Å.

The first layer 130b1 has a lower concentration of oxygen vacancies than the second layer 130b2, and the first layer 130b1 has a relatively dense structure. The first layer 130b1 may serve as a barrier to inhibit oxygen exchange between the first electrode 120 and the second layer 130b2 when a reset operation, in which the conductive filaments are disconnected, is performed. Because the first layer 130b1 serves as the barrier to oxygen when the reset operation, the occurrence of a negative-set phenomenon may be delayed. The negative-set phenomenon means that when the reset voltage increases, the oxygen vacancies in the disconnected conductive filaments re-aggregate, leading to re-growth of the conductive filaments. In this way, the first layer 130b1 can enhance the ability of the resistance change layer 130 to resist electrical breakdown, thereby improving the electrical reliability of the resistance change layer 130.

Referring back to FIG. 1, the oxygen vacancy reservoir layer 140 is disposed on the resistance change layer 130. The oxygen vacancy reservoir layer 140 may provide oxygen vacancies to the resistance change layer 130 when a forming voltage or a set voltage is applied between the first electrode 120 and the second electrode 160. In addition, the oxygen vacancy reservoir layer 140 may receive the oxygen vacancies from the resistance change layer 130 when a reset voltage is applied between the first electrode 120 and the second electrode 160. The polarity of the reset voltage may be opposite to the polarities of the forming voltage and the set voltage.

In an embodiment, the oxygen vacancy reservoir layer 140 may include metal having reactivity with oxygen. The metal may include, for example, tantalum (Ta), titanium (Ti), zirconium (Zr), vanadium (V), tungsten (W), ruthenium (Ru), or a combination of two or more thereof.

Referring to FIG. 1, the thermal confinement electrode layer 150 is disposed on the oxygen vacancy reservoir layer 140. The thermal confinement electrode layer 150 may perform a role of inhibiting heat from being conducted to the second electrode 160 through the thermal confinement electrode layer 150. In addition, the thermal confinement electrode layer 150 may function as an electrode of the semiconductor device 1 when together with the second electrode 160. That is, in the semiconductor device 1 of FIG. 1, the first electrode 120 may function as a lower electrode, and the thermal confinement electrode layer 150 and the second electrode 160 may function as upper electrodes.

The thermal confinement electrode layer 150 may include an electrode material having lower thermal conductivity than the material of the second electrode 160. The electrode material may be a resistor having a predetermined electrical conductivity. As an example, the thermal confinement electrode layer 150 has a thickness within a range of 10 Å through 100 Å.

In an embodiment, thermal confinement electrode layer 150 may include metal silicon nitride. As an example, the thermal confinement electrode layer 150 may include tungsten silicon nitride, titanium silicon nitride, aluminum silicon nitride, or a combination of two or more thereof. In another embodiment, the thermal confinement electrode layer 150 may contain carbon (C). As an example, the thermal confinement electrode layer 150 may include a carbon layer. The carbon layer may have, for example, an amorphous structure. The carbon layer may be, for example, doped with nitrogen (N). The carbon layer may be controlled to have different thermal conductivities, while having substantially the same electrical conductivity, depending on a doping method or a deposition method. In an embodiment of the present disclosure, the carbon layer may be formed to have reduced thermal conductivity relative to other layers in the device.

The thermal confinement electrode layer 150 can inhibit the heat generated in the resistance change layer 130 and the oxygen vacancy reservoir layer 140 from being transferred to the contact electrode 190 through the second electrode 160 and from escaping to the outside of the semiconductor device 1 thereafter. The heat generated in the resistance change layer 130 and the oxygen vacancy reservoir layer 140 results from operations such as the set operation and the reset operation of the semiconductor device 1. The thermal confinement electrode layer 150 can maintain or preserve the heat within the resistance change layer 130 and the oxygen vacancy reservoir layer 140.

Referring to FIG. 1, the second electrode 160 is disposed on the thermal confinement electrode layer 150. The second electrode 160 may include a conductive material. The second electrode 160 may include, for example, metal, conductive metal nitride, conductive metal carbide, conductive metal silicide, or conductive metal oxide. The conductive material of the second electrode 160 may be the same as or different from the conductive material of the first electrode 120.

A width W3 of the second electrode 160 may be smaller than the width W2 of the first electrode 120 in a lateral direction (for example, the x-direction). Referring to FIG. 1, the width in the lateral direction may decrease for each layer from the first electrode 120 to the second electrode 160. Accordingly, the semiconductor device 1 shown in FIG. 1 may have a trapezoidal cross-sectional shape.

Referring to FIG. 1, a protective insulation layer 170 is disposed on the base insulation layer 110. The protective insulation layer 170 is disposed to cover a side surface 120S of the first electrode 120, a side surface 130S of the resistance change layer 130, a side surface 140S of the oxygen vacancy reservoir layer 140, a side surface 150S of the thermal confinement electrode layer 150, and a side surface 160S and an upper surface 160U of the second electrode 160. The side surfaces may form a surface that continuously tapers from the side surface 120S through the side surface 160S. The protective insulation layer 170 can serve as a barrier to inhibit materials from diffusing from outside of the semiconductor device 1 into the semiconductor device 1. The protective insulation layer 170 may include an insulating material having a denser structure than an interlayer insulation layer 180 (described below) in order to perform the function of a barrier. The insulating material may include, for example, silicon oxide, silicon nitride, or silicon oxynitride.

Referring to FIG. 1, the interlayer insulation layer 180 is disposed to cover the protective insulation layer 170, which is disposed on the base insulation layer 110. The interlayer insulation layer 180 may include an electrically insulating material. The interlayer insulation layer 180 has a flattened upper surface common to an upper surface of the contact electrode 190. The interlayer insulation layer 180 may include an insulating material having a low dielectric constant, for example, oxide, nitride, or oxynitride.

The contact electrode 190 is disposed to penetrate the protective insulation layer 170 and the interlayer insulation layer 180 and to contact the second electrode 160. The contact electrode 190 may include a conductive material. The contact electrode 190 may include, for example, metal, conductive metal nitride, conductive metal carbide, conductive metal silicide, or conductive metal oxide.

The contact electrode 190 may be connected to a bit line that applies an operation voltage.

As described above, semiconductor devices according to embodiments of the disclosure include a first electrode, a resistance change layer disposed on the first electrode, an oxygen vacancy reservoir layer disposed on the resistance change layer, a thermal confinement electrode layer disposed on the oxygen vacancy reservoir layer, and a second electrode disposed on the thermal confinement electrode layer. The thermal confinement electrode layer has lower thermal conductivity than an adjacent second electrode, thereby helping to confine the heat generated during set operations and reset operations inside the semiconductor device.

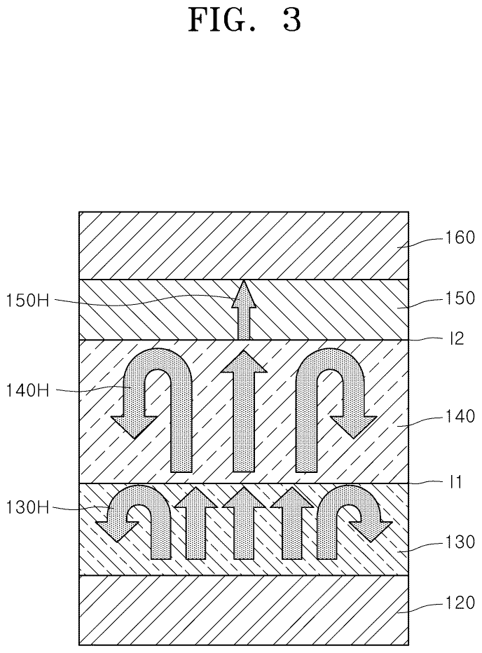

FIG. 3 is a schematic diagram illustrating the flow of internal heat during an operation of a semiconductor device according to an embodiment of the present disclosure. The schematic diagram of FIG. 3 schematically illustrates the flow of the heat generated inside a semiconductor device 1 of FIG. 1 when a set operation or a reset operation is performed in the semiconductor device 1.

Referring to the schematic diagram of FIG. 3, when a set voltage or a reset voltage is applied to the resistance change layer 130, the heat generated in the resistance change layer 130 may move toward the oxygen vacancy reservoir layer 140. A portion of the generated heat may pass through an interface I1 between the resistance change layer 130 and the oxygen vacancy reservoir layer 140, and transfer into the oxygen vacancy reservoir layer 140. Another portion of the generated heat might not move into the oxygen vacancy reservoir layer 140 and remain in the resistance change layer 130. In FIG. 3, the flow of the generated heat within the resistance change layer 130 is indicated as “130H.”

The heat inside the oxygen vacancy reservoir layer 140 transferred from the resistance change layer 130 may move to an interface 12 between the oxygen vacancy reservoir layer 140 and the thermal confinement electrode layer 150. Most of the heat that moves to the interface 12 is blocked by the thermal confinement electrode layer 150, which has low thermal conductivity, and remain inside the oxygen vacancy reservoir layer 140. As the temperature of the oxygen vacancy reservoir layer 140 increases, the flow of the heat from the resistance change layer 130 to the oxygen vacancy reservoir layer 140 may decrease.

Meanwhile, a portion of the heat inside the oxygen vacancy reservoir layer 140 may pass through the interface 12 and move into the thermal confinement electrode layer 150. Because the thermal conductivity of the thermal confinement electrode layer 150 is low, the flow of the heat moving toward the second electrode 160 within the thermal confinement electrode layer 150 may be limited. In FIG. 3, the heat flow within the oxygen vacancy reservoir layer 140 and the heat flow within the thermal confinement electrode layer 150 are indicated as “140H” and “150H”, respectively.

Because the thermal confinement electrode layer 150 is disposed between the oxygen vacancy reservoir layer 140 and the second electrode 160, thermal energy can accumulate in the resistance change layer 130 during operations of the semiconductor device (1 of FIG. 1). Accordingly, the internal temperature of the resistance change layer 130 can be higher when compared to a device in which the thermal confinement electrode layer 150 is not provided.

When the internal temperature of the resistance change layer 130 rises, the formation and disconnection of conductive filaments within the resistance change layer 130 becomes more stable and uniform. As the internal temperature rises, the distribution of oxygen vacancies within the resistance change layer may become more uniform. Accordingly, during the forming operation or set operation of the semiconductor device (1 in FIG. 1), multiple weaker filaments may be formed with a relatively higher probability than a single stronger filament within the resistance change layer 130. A strong filament may mean a filament having a large width and a large cross-sectional area, and a weak filament may mean a filament having a relatively small width and a relatively small cross-sectional area. Accordingly, when a resistance switching operation occurs within the resistance change layer 130 of the semiconductor device, and multiple weak filaments are formed, the change in conductance may occur gradually rather than abruptly. As a result, the linearity between the plurality of conductance values stored in the semiconductor device may be improved, thereby improving the analog characteristics of the stored signal information.

In the above-described Paper of the inventor of the present disclosure, a ReRAM synapse cell (RSC) having a thermal enhanced layer corresponding to the thermal confinement electrode layer of an embodiment of the present disclosure is disclosed. The RSC having the thermal enhanced layer can have improved resistance switching characteristics, compared to an RSC without the thermal enhanced layer. As an example, in the RSC described in the Paper, a forming voltage V_{Form}, which is the voltage at which the first conductive filament is generated through the forming operation, may decrease. The forming voltage decreases because as the internal temperature of the resistance change layer 130 rises, the aggregation of the oxygen vacancies is promoted so that the conductive filament is generated at a relatively low voltage.

Additionally, compared to an RSC without a thermal enhancement layer, in the RSC with the thermal enhancement layer, the breakdown voltage V_{BD} may relatively increase. The breakdown voltage V_{BD} may refer to a voltage at which a negative-set phenomenon occurs during a reset operation. The negative-set phenomenon may refer to a phenomenon in which the conductive filaments disconnected through the reset operation re-grow through re-aggregation of the oxygen vacancies. In an example, a negative-set phenomenon may be confirmed from the fact that, during a reset operation, the conductance value of the resistance change layer rapidly increases when the reset voltage reaches a voltage greater than a predetermined level.

In addition, according to the above-described Paper, an RSC having a thermal enhancement layer can improve data linearity for multiple weights compared to an RSC without a thermal enhancement layer. For example, the weights can be numbers stored in the RSC for a multiplication and accumulation (MAC) operation.

In the above-described Paper, the improvement of the data linearity is confirmed through the following process. First, multiple target weights (that is, ideal outputs) that change linearly are set, and operation voltages that implement the multiple target weights are determined. The operation voltages may be applied to the RSCs to confirm deviations between the actually measured weights (that is, the real outputs) and the target weights (that is, the ideal outputs). In the Paper, it can be confirmed that the RSCs with thermal enhancement layers have a smaller deviation between the target weight and the measured weight at multiple operation voltages compared to the RSCs without thermal enhancement layers. The improvement in the data linearity may mean that the analog characteristics of the RSC are improved.

Additionally, according to the Paper, the RSCs with a thermal enhancement layer can have improved data retention over time, compared to the RSCs without a thermal enhancement layer. In other words, the Paper confirms that the RSCs with a thermal enhancement layer have relatively superior weight degradation characteristics after a predetermined period of time, compared to the RSCs without a thermal enhancement layer.

In conclusion, semiconductor devices of embodiments of the present disclosure include a thermal confinement electrode layer to improve resistance switching characteristics such as forming voltage, breakdown voltage, etc. and to improve reliability in data linearity, information retention, etc.

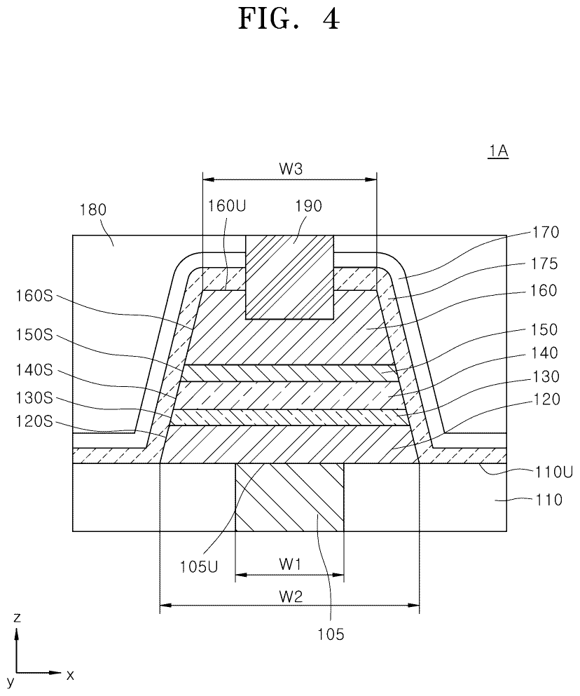

FIG. 4 is a schematic cross-sectional view illustrating a semiconductor device according to another embodiment of the present disclosure. Referring to FIG. 4, a semiconductor device 1A further includes a thermal confinement insulation layer 175, compared to a semiconductor device 1 described above with reference to FIG. 1.

The thermal confinement insulation layer 175 is disposed to cover a side surface 120S of a first electrode 120, a side surface 130S of a resistance change layer 130, a side surface 140S of an oxygen vacancy reservoir layer 140, a side surface 150S of a thermal confinement electrode layer 150, and a side surface 160S and an upper surface 160U of an second electrode 160. Specifically, the thermal confinement insulation layer 175 is disposed to contact the first electrode 120, the resistance change layer 130, the oxygen vacancy reservoir layer 140, the thermal confinement electrode layer 150, and the second electrode 160. The thermal confinement insulation layer 175 is a layer that can further limit the release of heat inside a semiconductor device 1A from being released through the side surfaces 120S, 130S, 140S, 150S, and 160S and through the upper surface 160U of the second electrode 160.

The thermal confinement insulation layer 175 may include a dielectric having low thermal conductivity. The thermal confinement insulation layer 175 may include, for example, an oxide dielectric or an organic dielectric material. Specifically, the thermal confinement insulation layer 175 may include a fluorine-doped silicon oxide, a carbon-doped silicon oxide, a metal-organic framework, and the like. The thermal confinement insulation layer 175 may have a porous structure. The thermal confinement insulation layer 175 may have electrically insulating properties.

A protective insulation layer 170 is disposed on the thermal confinement insulation layer 175. The protective insulation layer 170 may include an insulating material of a relatively dense structure having a higher density than the thermal confinement insulation layer 175. The protective insulation layer 170 may include a different insulating material from the thermal confinement insulation layer 175. The insulating material of the protective insulation layer 170 may include, for example, silicon oxide, silicon nitride, or silicon oxynitride.

An interlayer insulation layer 180 is disposed on the protective insulation layer 170. A contact electrode 190 is disposed to penetrate the interlayer insulation layer 180, the protective insulation layer 170, and the thermal confinement insulation layer 175 and to contact the second electrode 160.

In some embodiments, the protective insulation layer 170 may be omitted, and the interlayer insulation layer 180 is disposed to directly contact the thermal confinement insulation layer 175.

Although not illustrated, other embodiments may include thermal confinement insulation layers 175 with various variations. For example, the thermal confinement insulation layer 175 may be disposed to cover at least the side surfaces 130S and 140S of the resistance change layer 130 and the oxygen vacancy reservoir layer 140, respectively, but not disposed to cover at least one of the side surface 120S of the first electrode 120, the side surface 150S of the thermal confinement electrode layer 150, and the side surface 160S and the upper surface 160U of the second electrode 160. In this case, the protective insulation layer 170 or the interlayer insulation layer 180 may be disposed directly on the at least one of the side surface 120S of the first electrode 120, the side surface 150S of the thermal confinement electrode layer 150, and the side surface 160S and the upper surface 160U of the second electrode 160, that is, where the thermal confinement insulation layer 175 is not disposed.

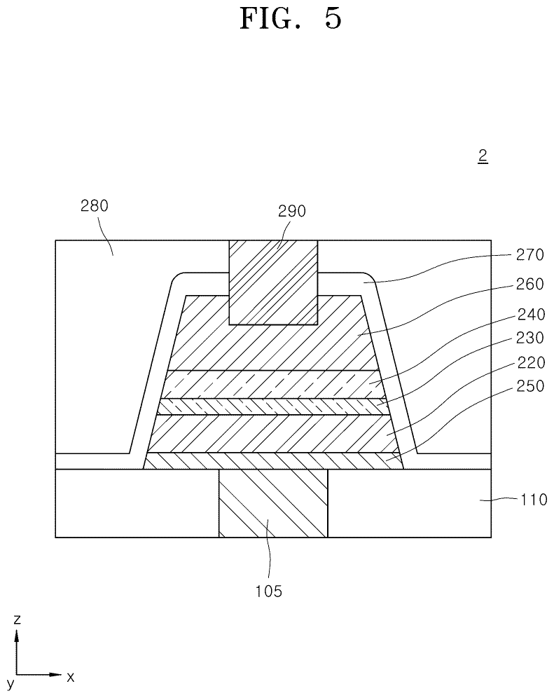

FIG. 5 is a schematic cross-sectional view illustrating a semiconductor device according to another embodiment of the present disclosure. Referring to FIG. 5, a semiconductor device 2 has a configuration with a different arrangement of a thermal confinement electrode layer 250 compared to a semiconductor device 1 described above with reference to FIG. 1.

Referring to FIG. 5, a thermal confinement electrode layer 250 is disposed on a contact plug electrode 105 and a base insulation layer 110. The thermal confinement electrode layer 250 is disposed to cover the contact plug electrode 105 and potions of the base insulation layer 110. A first electrode 220 is disposed on the thermal confinement electrode layer 250. A resistance change layer 230, an oxygen vacancy reservoir layer 240, and a second electrode 260 are sequentially disposed on the first electrode 220.

In addition, a protective insulation layer 270 is disposed over the contact plug electrode 105 and on the base insulation layer 110 to cover a side surface of the thermal confinement electrode layer 250, a side surface of the first electrode 220, a side surface of the resistance change layer 230, a side surface of the oxygen vacancy reservoir layer 240, and a side surface and an upper surface of the second electrode 260. An interlayer insulation layer 280 is disposed to cover the protective insulation layer 270. A contact electrode 290 is disposed to penetrate the interlayer insulation layer 280 and the protective insulation layer 270 and to contact the second electrode 260.

The configurations of the first electrode 220, the resistance change layer 230, the oxygen vacancy reservoir layer 240, the second electrode 260, the protective insulation layer 270, the interlayer insulation layer 280, and the contact electrode 290 are substantially the same as the configurations of the first electrode 120, the resistance change layer 130, the oxygen vacancy reservoir layer 140, the second electrode 160, the protective insulation layer 170, the interlayer insulation layer 180, and the contact electrode 190 of a semiconductor device 1 of FIG. 1. The thermal confinement electrode layer 250 is substantially the same as the thermal confinement electrode layer 150 of a semiconductor device 1 of FIG. 1, except for its arrangement within a semiconductor device 2 of FIG. 5.

The thermal confinement electrode layer 250 serves to inhibit heat from being conducted from the first electrode 220 through the thermal confinement electrode layer 250 to the contact plug electrode 105. Specifically, the thermal confinement electrode layer 250 is disposed between the contact plug electrode 105 and the first electrode 220, so that the heat generated within the resistance change layer 230 and the oxygen vacancy reservoir layer 240 during a set operation or a reset operation of the semiconductor device 2 can be suppressed from transfer to the substrate below the contact plug electrode 105 and the base insulation layer 110. Additionally, the thermal confinement electrode layer 250 can function as a connecting electrode that electrically connects the contact plug electrode 105 to the first electrode 220.

The thermal confinement electrode layer 250 may include an electrode material having lower thermal conductivity than the contact plug electrode 105 and the first electrode 220. In addition, the electrode material may be a resistor having a predetermined electrical conductivity.

In some embodiments, the semiconductor device 2 further includes a thermal confinement insulation layer corresponding to a thermal confinement insulation layer 175 of a semiconductor device 1A of FIG. 4. It is possible to further alleviate the heat inside the semiconductor device 2 from being released through side surfaces of layers in the semiconductor device 2 or through the upper surface of a second electrode 260 by using an additional thermal confinement insulation layer.

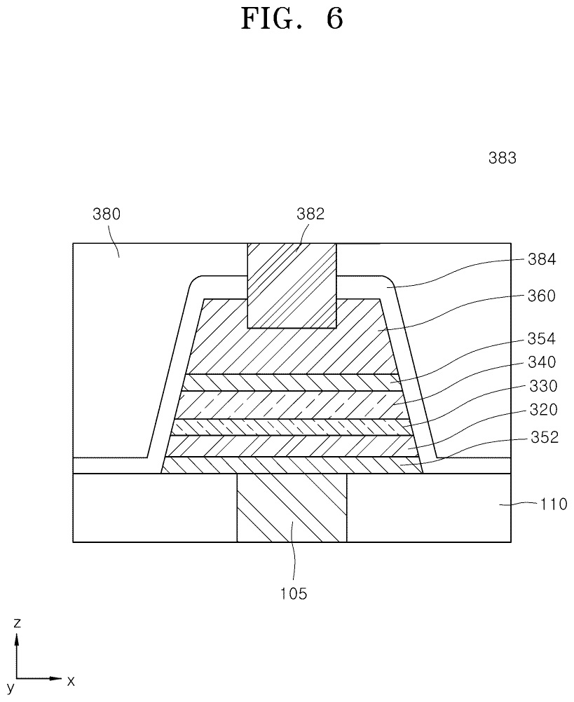

FIG. 6 is a schematic cross-sectional view illustrating a semiconductor device according to another embodiment of the present disclosure. Referring to FIG. 6, a semiconductor device 3 includes a pair of thermal confinement electrode layers arranged at different positions within the semiconductor device.

Referring to FIG. 6, a first thermal confinement electrode layer 352 is disposed on a contact plug electrode 105 and a base insulation layer 110. A first electrode 320 is disposed on the first thermal confinement electrode layer 352. A resistance change layer 330 and an oxygen vacancy reservoir layer 340 are sequentially disposed on the first electrode 320. A second thermal confinement electrode layer 354 is disposed on the oxygen vacancy reservoir layer 340. A second electrode 360 is disposed on the second thermal confinement electrode layer 354.

In addition, a protective insulation layer 370 is disposed to cover a side surface of the first thermal confinement electrode layer 352, a side surface of the first electrode 320, a side surface of the resistance change layer 330, a side surface of the oxygen vacancy reservoir layer 340, a side surface of the second thermal confinement electrode layer 354, and a side surface and an upper surface of the second electrode 360. An interlayer insulation layer 380 is disposed on the protective insulation layer 370. A contact electrode 390 is disposed to penetrate the interlayer insulation layer 380 and the protective insulation layer 370 and to contact the second electrode 360.

The configurations of the first electrode 320, the resistance change layer 330, the oxygen vacancy reservoir layer 340, the second electrode 360, the protective insulation layer 370, the interlayer insulation layer 380, and the contact electrode 390 are substantially the same as the configurations of the first electrode 120, the resistance change layer 130, the oxygen vacancy reservoir layer 140, the second electrode 160, the protective insulation layer 170, the interlayer insulation layer 180, and the contact electrode 190, respectively, which are described above with reference to FIG. 1. The configuration of the first thermal confinement electrode layer 352 is substantially the same as the configuration of a thermal confinement electrode layer 250 of a semiconductor device 2 of FIG. 5, and the configuration of the second thermal confinement electrode layer 354 is substantially the same as a configuration of a thermal confinement electrode layer 150 of a semiconductor device 1 of FIG. 1.

In an embodiment, the first thermal confinement electrode layer 352 is disposed between the contact plug electrode 105 and the first electrode 320, and the second thermal confinement electrode layer 354 is disposed between the oxygen vacancy reservoir layer 340 and the second electrode 360. Accordingly, it is possible to suppress transfer of the heat, generated inside the resistance change layer 330 and the oxygen vacancy reservoir layer 340 during set operations and reset operations of the semiconductor device 3, to the substrate through the contact plug electrode 105 and to the outside of the semiconductor device 3 through the second electrode 360 and the contact electrode 390.

In some embodiments, the semiconductor device 3 may further include a thermal confinement insulation layer corresponding to a thermal confinement insulation layer 175 of a semiconductor device 1A of FIG. 4. With this additional thermal confinement insulation layer, more suppression of heat transfer is possible to inhibit the heat inside the semiconductor device 3 from being released through the side surfaces of the semiconductor device 3 or through the upper surface of the second electrode 360.

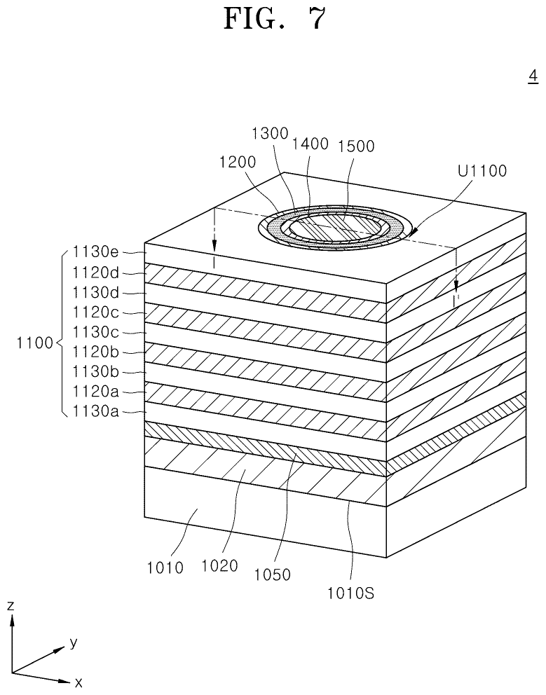

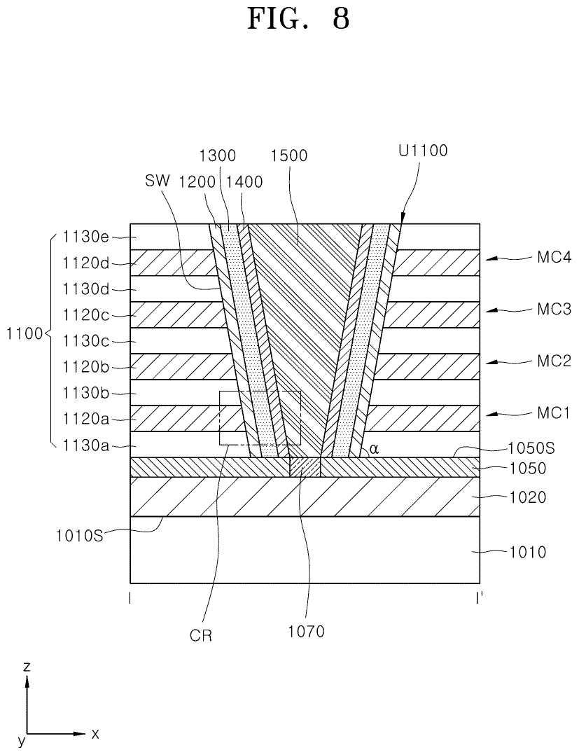

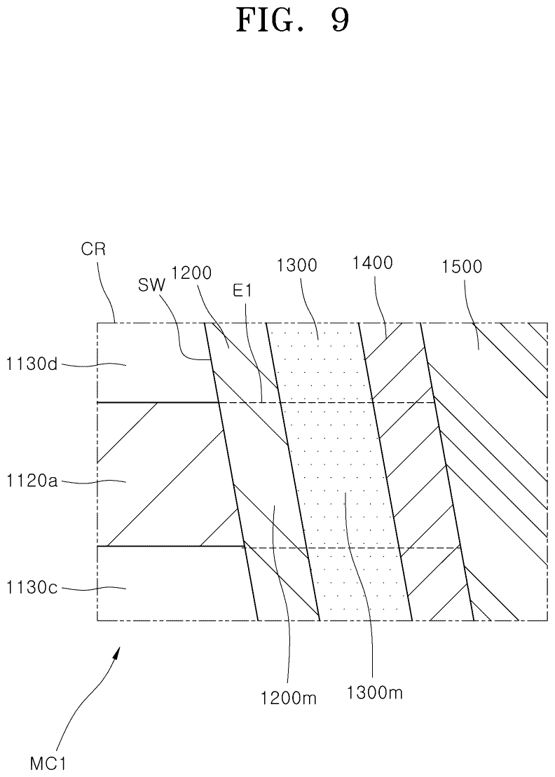

FIG. 7 is a schematic perspective view illustrating a semiconductor device according to another embodiment of the present disclosure. FIG. 8 is a schematic cross-sectional view of the semiconductor device of FIG. 7 taken along a line I-I′. FIG. 9 is an enlarged view of a region “CR” of FIG. 8.

Referring to FIG. 7 to FIG. 9, a semiconductor device 4 includes a substrate 1010 and an electrode structure 1100 disposed over the substrate 1010. The electrode structure 1100 includes first to fifth interlayer insulation layers 1130a, 1130b, 1130c, 1130d, and 1130e and first to fourth horizontal electrode layers 1120a, 1120b, 1120c, and 1120d which are alternately disposed. The semiconductor device 4 includes a hole U1100 penetrating the electrode structure 1100 over the substrate 1010. In addition, the semiconductor device 4 includes a resistance change layer 1200, an oxygen vacancy reservoir layer 1300, and a thermal confinement electrode layer 1400 that are sequentially disposed along a sidewall surface SW of the hole U1100. That is, the resistance change layer 122 is disposed on the sidewall SW of the U1100, the oxygen vacancy reservoir layer 1300 is disposed on a side surface of the resistance change layer 1200 within the hole U1100, and the thermal confinement electrode layer 1400 is disposed on a side surface of the oxygen vacancy reservoir layer 1300 within the hole U1100. In addition, the semiconductor device 4 includes a vertical electrode layer 1500 disposed on a side surface of the thermal confinement electrode layer 1400 within the hole U1100.

The semiconductor device 4 includes first to fourth memory cells MC1, MC2, MC3, and MC4, as shown in FIG. 8. The first memory cell MC1 includes a first resistance change region of the resistance change layer 1200 and a first oxygen vacancy region of the oxygen vacancy reservoir layer 1300 that are disposed at a position where a first horizontal electrode layer 1120a and the vertical electrode layer 1500 overlap each other in a lateral direction (e.g., x-direction). In FIG. 9, the first resistance change region 1200m of the resistance change layer 1200 and the first oxygen vacancy region 1300m of the oxygen vacancy reservoir layer 1300 that constitute the first memory cell MC1 are specifically illustrated, as an example. As described, the first resistance change region 1200m and the first oxygen vacancy region 1300m may be regions of the resistance change layer 1200 and the oxygen vacancy reservoir layer 1300, respectively, arranged at the position where the first horizontal electrode layer 1120a and the vertical electrode layer 1500 overlap each other in the lateral direction.

The first resistance change region 1200m and the first oxygen vacancy region 1300m may be regions to which an electric field E1 formed by a set voltage or a reset voltage is applied when the set voltage or the reset voltage is applied between the first horizontal electrode layer 1120a and the vertical electrode layer 1500.

Referring again to FIG. 7 to FIG. 9, the second memory cell MC2 includes a second resistance change region of the resistance change layer 1200 and a second oxygen vacancy region of the oxygen vacancy reservoir layer 1300 that are disposed at a position where a second horizontal electrode layer 1120b and the vertical electrode layer 1500 overlap each other in the lateral direction. The third memory cell MC3 includes a third resistance change region of the resistance change layer 1200 and a third oxygen vacancy region of the oxygen vacancy reservoir layer 1300 that are disposed at a position where a third horizontal electrode layer 1120c and the vertical electrode layer 1500 overlap each other in the lateral direction. The fourth memory cell MC4 includes a fourth resistance change region of the resistance change layer 1200 and a fourth oxygen vacancy region of the oxygen vacancy reservoir layer 1300 that are disposed at a position where a fourth horizontal electrode layer 120d and the vertical electrode layer 1500 overlap each other in the lateral direction.

Referring to FIG. 7 to FIG. 9, the substrate 1010 is formed of various materials to which a semiconductor integration process can be applied. For example, the substrate 1010 may be a semiconductor substrate, a conductive substrate, or an insulator substrate. In an embodiment, the substrate 1010 is a semiconductor substrate. The semiconductor substrate 1010 includes, for example, silicon (Si), germanium (Ge), gallium arsenide (GaAs), or the like. The semiconductor substrate 1010 may include n-type or p-type doped well regions.

A base device structure 1020 is disposed on the substrate 1010. The base device structure 1020 includes a plurality of levels of conductive layers, conductive contact patterns connecting the plurality of levels of conductive layers to each other, and interlayer insulation layers disposed between the plurality of levels of conductive layers. Some of the plurality of levels of conductive layers may be electrically connected to the well regions of the substrate 1010.

In an embodiment, the base device structure 1020 includes various integrated circuits formed by the conductive layers. The integrated circuits include peripheral logic circuits or wiring circuits. As an example, the integrated circuits may include field effect transistors, resistor elements, capacitors, or a combination of two or more thereof.

A base insulation layer 1050 is disposed on the base device structure 1020. The base insulation layer 1050 separates the base device structure 1020 and the electrode structure 1100 from each other in a vertical direction, that is, z-direction. The base insulation layer 1050 includes, for example, oxide, nitride, oxynitride, or a combination of two or more thereof.

A contact plug 1070 is disposed within the base insulation layer 1050. The contact plug 1070 electrically connects the vertical electrode layer 1500 to a conductive layer within the base device structure 1020. The contact plug 1070 includes, for example, a doped semiconductor material, metal, conductive metal nitride, conductive metal oxide, conductive metal silicide, or a combination of two or more thereof.

The electrode structure 1100 is disposed on the base insulation layer 1050. The electrode structure 1100 includes the first to fourth horizontal electrode layers 1120a, 1120b, 1120c, and 1120d that are disposed to be spaced apart from each other in the vertical direction, that is, z-direction. Each of the first to fourth horizontal electrode layers 1120a, 1120b, 1120c, and 1120d is disposed on a plane parallel to a surface 1010S of the substrate 1010. The first to fourth horizontal electrode layers 1120a, 1120b, 1120c, and 1120d extend in a direction parallel to the surface 1010S of the substrate 1010, for example, in the x-direction or y-direction.

Each of the first to fourth horizontal electrode layers 1120a, 1120b, 1120c, and 1120d includes a conductive material. The conductive material includes, for example, metal, metal nitride, metal oxide, metal silicide, or a doped semiconductor material. The conductive material includes, for example, tungsten (W), aluminum (Al), copper (Cu), tantalum (Ta), titanium (Ti), gold (Au), platinum (Pt), silver (Ag), ruthenium (Ru), iridium (Ir), molybdenum (Mo), tungsten nitride, titanium nitride, tantalum nitride, doped silicon (Si), or a combination of two or more thereof.

In addition, the electrode structure 1100 includes the first to fifth interlayer insulation layers 1130a, 1130b, 1130c, 1130d, and 1130e. The first interlayer insulation layer 1130a is disposed between the base insulation layer 1050 and the first horizontal electrode layer 1120a. The second interlayer insulation layer 1130b is disposed between the first horizontal electrode layer 1120a and the second horizontal electrode layer 1120b, the third interlayer insulation layer 1130c is disposed between the second horizontal electrode layer 1120b and the third horizontal electrode layer 1120c, and the fourth interlayer insulation layer 1130d is disposed between the third horizontal electrode layer 1120c and the fourth horizontal electrode layer 1120d. The fifth interlayer insulation layer 1130e is disposed on the fourth horizontal electrode layer 1120d. Each of the first to fifth interlayer insulation layers 1130a, 1130b, 1130c, 1130d, and 1130e includes an insulating material. The insulating material may include, for example, oxide, nitride, oxynitride, or a combination of two or more thereof.

Referring to FIG. 7 to FIG. 9, the electrode structure 1100 includes the first to fourth horizontal electrode layers 1120a, 1120b, 1120c, and 1120d, but the number of horizontal electrode layers may not necessarily be limited to four. The electrode structure 1100 may include a variety of other numbers of horizontal electrode layers. Accordingly, the interlayer insulation layers of the electrode structure 1100 may be disposed in various numbers to insulate the various numbers of horizontal electrode layers from each other in the z-direction. In addition, the semiconductor device 4 may include various numbers of memory cells corresponding to the number of horizontal electrode layers.

Referring to FIG. 7 to FIG. 9, the hole U1100 penetrating the electrode structure 1100 is formed on the base insulation layer 1050. Referring to FIG. 7, the hole U1100 may have a circular shape on the x-y plane. In some embodiments, the hole U1100 may have an elliptical or polygonal shape on the x-y plane.

Referring to FIG. 8 and FIG. 9, side surfaces of the first to fifth interlayer insulation layers 1130a, 1130b, 1130c, 1130d, and 1130e and side surfaces of the first to fourth horizontal electrode layers 1120a, 1120b, 1120c, and 1120d are exposed on the sidewall surface SW of the hole U1100. The sidewall surface SW of the hole U1100 has an inclination angle a with respect to a surface 1050S of the base insulation layer 1050. The inclination angle a may be an acute angle less than 90°, for example. In another embodiment not shown, the inclination angle a may be 90°.

Referring to FIG. 7 to FIG. 9, the resistance change layer 1200 is disposed along the sidewall surface SW of the hole U1100. The resistance change layer 1200 is disposed on the side surfaces of the first to fifth interlayer insulation layers 1130a, 1130b, 1130c, 1130d, and 1130e and the side surfaces of the first to fourth horizontal electrode layers 1120a, 1120b, 1120c, and 1120d. In addition, the oxygen vacancy reservoir layer 1300 is disposed on the resistance change layer 1200 within the hole U1100. The oxygen vacancy reservoir layer 1300 contacts the resistance change layer 1200.

The resistance change layer 1200 includes a resistance change material whose conductance, that is, electrical resistance, changes depending on a voltage or current applied to the resistance change layer 1200. The resistance change material maintains the changed conductance or electrical resistance after the applied voltage or current is removed.

In an embodiment, the resistance change material of the resistance change layer 1200 includes oxygen vacancies. The resistance change material may include metal oxide that does not satisfy the stoichiometric ratio. The resistance change material may include, for example, hafnium oxide, zirconium oxide, hafnium zirconium oxide, titanium oxide, aluminum oxide, or a combination of two or more thereof. The oxygen vacancies may be aggregated to form conductive filaments within the resistance change layer 1200 to electrically connect a predetermined horizontal electrode layer with the oxygen vacancy reservoir layer 1300 during the set operation of a predetermined memory cell of the semiconductor device 4. The oxygen vacancies may be separated from the conductive filaments during the reset operation of the semiconductor device 4. As a result, the conductive filaments may be disconnected.

In an embodiment, the resistance change layer 1200 may retain a plurality of conductance values that are distinct from each other as signal information. The plurality of conductance values may be changed substantially linearly depending on an operation voltage applied to the resistance change layer 1200. As an example, magnitudes of the plurality of conductance values may increase linearly in proportion to a magnitude of the operation voltage applied to the resistance change layer 1200. The magnitude of the applied operation voltage may be controlled by, for example, an amplitude of a direct current (DC) voltage, a width of a pulse voltage, or the number of times the pulse voltage is applied.

The oxygen vacancy reservoir layer 1300 may exchange the oxygen vacancies with the resistance change layer 1200. The oxygen vacancy reservoir layer 1300 provides the oxygen vacancies to the resistance change layer 1200 when the semiconductor device 4 performs a set operation of a predetermined memory cell. The oxygen vacancy reservoir layer 1300 receives the oxygen vacancies from the resistance change layer 1200 when the semiconductor device 4 performs a reset operation of a predetermined memory cell.

In an embodiment, the oxygen vacancy reservoir layer 1300 includes metal. The metal includes, for example, tantalum (Ta), titanium (Ti), zirconium (Zr), vanadium (V), tungsten (W), ruthenium (Ru), or a combination of two or more thereof. During the set operation, the metal may react with oxygen within the resistance change layer 1200 to be converted into metal oxide, thereby generating the oxygen vacancies provided to the resistance change layer 1200. During the reset operation, the metal oxide may be reduced to the metal, thereby generating the oxygen that is provided to the resistance change layer 1200. The oxygen may remove the oxygen vacancies in the resistance change layer 1200.

Referring to FIG. 7 to FIG. 9, the thermal confinement electrode layer 1400 is disposed on the oxygen vacancy reservoir layer 1300 within the hole U1100. The thermal confinement electrode layer 1400 is disposed to cover the oxygen vacancy reservoir layer 1300 along the sidewall surface SW of the hole U1100.

The thermal confinement electrode layer 1400 serves to inhibit heat inside the resistance change layer 1200 and the oxygen vacancy reservoir layer 1300 from being conducted to the vertical electrode layer 1500. The thermal confinement electrode layer 1400 may be an electrically conductive layer disposed to be in contact with the vertical electrode layer 1500. Accordingly, the thermal confinement electrode layer 1400 may serve as an electrode of the semiconductor device 4 together with the vertical electrode layer 1500. The thermal confinement electrode layer 1400 is disposed at a position facing the horizontal electrode layers 1120a, 1120b, 1120c, and 1120d with the resistance change layer 1200 and the oxygen vacancy reservoir layer 1300 interposed therebetween.

The thermal confinement electrode layer 1400 includes an electrically conductive material having lower thermal conductivity than the vertical electrode layer 1500. As an example, the thermal confinement electrode layer 1400 has a thickness of 10 Å to 100 Å. Because the thermal confinement electrode layer 1400 has the low thermal conductivity, the thermal confinement electrode layer 1400 may help heat generated during the set operation and reset operation of the semiconductor device 4 to be remained inside the semiconductor device 4.

In an embodiment, the thermal confinement electrode layer 1400 includes metal silicon nitride. As an example, the thermal confinement electrode layer 1400 may include tungsten silicon nitride, titanium silicon nitride, aluminum silicon nitride, or a combination of two or more thereof. In another embodiment, the thermal confinement electrode layer 1400 may include carbon (C). As an example, the thermal confinement electrode layer 1400 may include a carbon (C) layer. The carbon (C) layer may have an amorphous structure, as an example. The carbon (C) layer may be a carbon layer doped with nitrogen (N), as an example. The carbon layer (C) may be controlled to have different thermal conductivities while having the same electrical conductivity depending on a doping method or a deposition method. In an embodiment of the present disclosure, the thermal conductivity of the carbon (C) layer may be decreased by controlling the doping method or the deposition method.

Referring to FIG. 7 to FIG. 9, the vertical electrode layer 1500 is disposed on the thermal confinement electrode layer 1400 within the hole U1100. The vertical electrode layer 1500 is disposed to fill the hole U1100 in which the resistance change layer 1200, the oxygen vacancy reservoir layer 1300, and the thermal confinement electrode layer 1400 are disposed. The vertical electrode layer 1500 extends in a direction perpendicular to the surface 1010S of the substrate 1010, that is, the z-direction.

The vertical electrode layer 1500 includes a conductive material. The conductive material may include, for example, metal, conductive metal nitride, conductive metal carbide, conductive metal silicide, conductive metal oxide, or a combination of two or more thereof. The conductive material of the vertical electrode layer 1500 may be the same as the conductive material of each of the horizontal electrode layers 1120a, 1120b, 1120c, and 1120d.

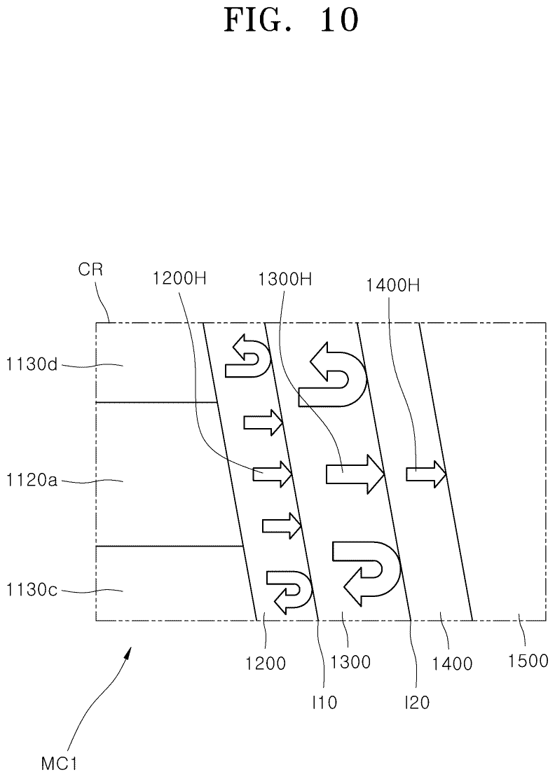

FIG. 10 is a schematic view illustrating the flow of internal heat during an operation of a semiconductor device according to another embodiment of the present disclosure. The schematic view of FIG. 10 schematically illustrates the flow of the heat generated inside the semiconductor device 4 when a set operation or a reset operation is performed in the memory cell MC1 of FIG. 9, for convenience.

Referring to the schematic view of FIG. 10, when a set voltage or a reset voltage is applied to the resistance change layer 1200, the heat generated in the resistance change layer 1200 moves toward the oxygen vacancy reservoir layer 1300. A portion of the heat passes through an interface 110 between the resistance change layer 1200 and the oxygen vacancy reservoir layer 1300 and is transferred into the oxygen vacancy reservoir layer 1300, and another portion of the heat does not move to the oxygen vacancy reservoir layer 1300 and remains in the resistance change layer 1200. In FIG. 10, the flow of the heat inside the resistance change layer 1200 is indicated as “1200H”.

The heat conducted from the resistance change layer 1200 and the heat inside the oxygen vacancy reservoir layer 1300 move to an interface 120 between the oxygen vacancy reservoir layer 1300 and the thermal confinement electrode layer 1400. Most of the heat moved to the interface 120 is blocked by the thermal confinement electrode layer 1400 with low thermal conductivity to be remained inside the oxygen vacancy reservoir layer 1300. Accordingly, the temperature of the oxygen vacancy reservoir layer 1300 is increased. As the temperature of the oxygen vacancy reservoir layer 1300 is increased, the flow of the heat conducted from the resistance change layer 1200 to the oxygen vacancy reservoir layer 1300 is decreased. In FIG. 10, the flow of the heat inside the oxygen vacancy reservoir layer 1300 is indicated as “1300H”.

Meanwhile, a portion of the heat inside the oxygen vacancy reservoir layer 1300 passes through the interface 120 with the thermal confinement electrode layer 1400 and moves into the thermal confinement electrode layer 1400. Because the thermal conductivity of the thermal confinement electrode layer 1400 is low, the flow of the heat moving in a direction of the vertical electrode layer 1500 within the thermal confinement electrode layer 1400 may be limited. In FIG. 10, the flow of the heat within the thermal confinement electrode layer 1400 is indicated as “1400H”.

As a result, the thermal confinement electrode layer 1400 is disposed between the oxygen vacancy reservoir layer 1300 and the vertical electrode layer 1500, so that the heat released from the resistance change layer 1200 into the vertical electrode layer 1500 during the set and reset operation of the semiconductor device 4 is decreased. Accordingly, the internal temperature of the resistance change layer 1200 is increased compared to a case where the thermal confinement electrode layer 1400 is not provided.

When the internal temperature of the resistance change layer 1200 rises, formation and disconnection of the conductive filaments within the resistance change region of the resistance change layer 1200 can be performed more stably. As the internal temperature is increased, distribution of the oxygen vacancies within the resistance change layer 1200 becomes more uniform. According to an embodiment, during the set operation of the semiconductor device 4, multiple weak filaments may be formed with a relatively higher probability than a single strong filament within the resistance change region of the resistance change layer 1200. The strong filament may mean a filament having a thick width and a large cross-sectional area, and the weak filament may mean a filament having a relatively thin width and a relatively small cross-sectional area. When a resistance switching operation occurs within the resistance change region of the resistance change layer 1200, the formation of multiple weak filaments may lead to a gradual change in conductance value rather than an abrup change. As a result, the linearity between the plurality of conductance values stored in the semiconductor device can be improved, so that the analog characteristics of signal information can be improved.

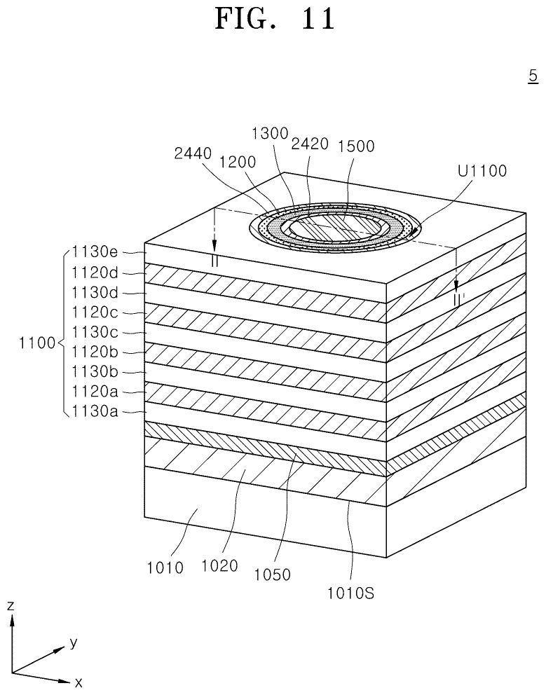

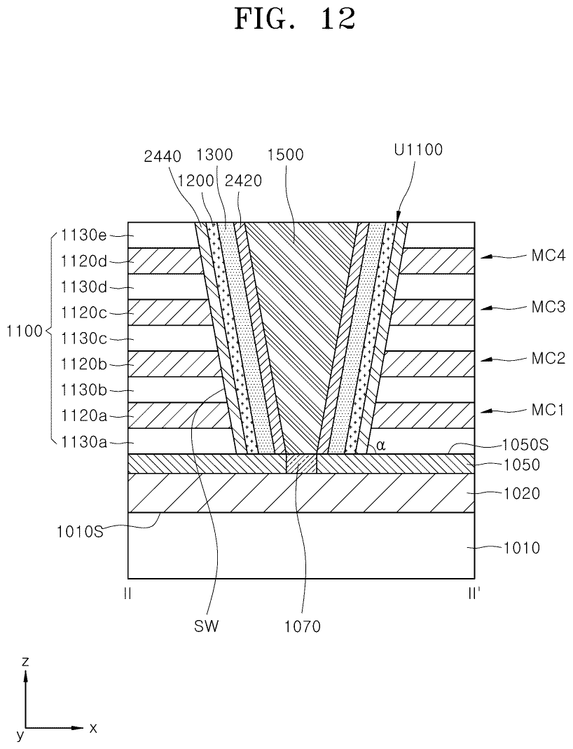

FIG. 11 is a schematic cross-sectional view illustrating a semiconductor device according to another embodiment of the present disclosure. FIG. 12 is a cross-sectional view illustrating the semiconductor device of FIG. 11 taken along a line II-II′. In FIG. 11 and FIG. 12, the same reference numerals as in FIGS. 7 to 9 represent the same components, so duplicate descriptions are omitted.

Referring to FIG. 11 and FIG. 12, compared to the semiconductor device 4 described with reference to FIG. 7 to FIG. 9, a semiconductor device 5 includes two thermal confinement electrode layers 2420 and 2440. A first thermal confinement electrode layer 2420 is disposed between an oxygen vacancy reservoir layer 1300 and a vertical electrode layer 1500. A configuration of the first thermal confinement electrode layer 2420 is substantially the same as a configuration of the thermal confinement electrode layer 1400 of the semiconductor device 4.

A second thermal confinement electrode layer 2440 is disposed between an electrode structure 1100 and a resistance change layer 1200 along a sidewall surface SW of a hole U1100. The second thermal confinement electrode layer 2440 contacts side surfaces of first to fourth horizontal electrode layers 1120a, 1120b, 1120c, and 1120d and side surfaces of first to fifth interlayer insulation layers 1130a, 113b0, 1130c, 1130d, and 1130e.

The second thermal confinement electrode layer 2440 may serve to inhibit heat inside the resistance change layer 1200 from being conducted to the electrode structure 1100. In addition, the second thermal confinement electrode layer 2440 may be electrically connected to the horizontal electrode layers 1120a, 1120b, 1120c, and 1120d.

The second thermal confinement electrode layer 2440 may include an electrically conductive material having lower conductivity than each of the first to fourth horizontal electrode layers 1120a, 1120b, 1120c, and 1120d. The second thermal confinement electrode layer 2440 may include a substantially the same material as the first thermal confinement electrode layer 2420.

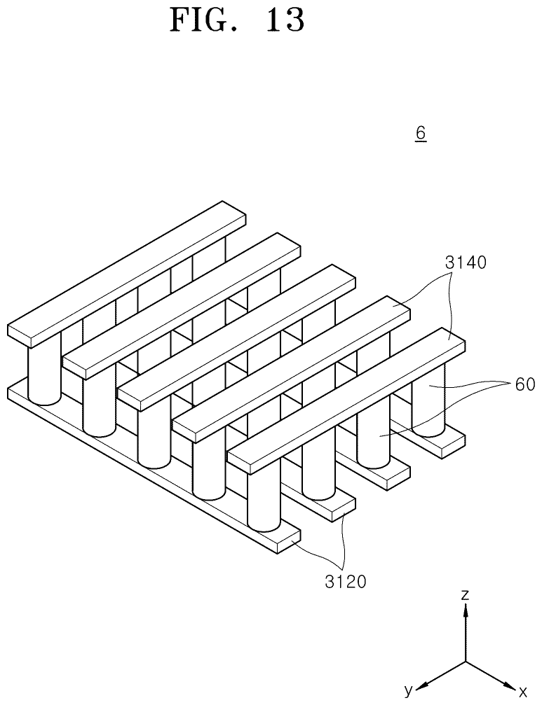

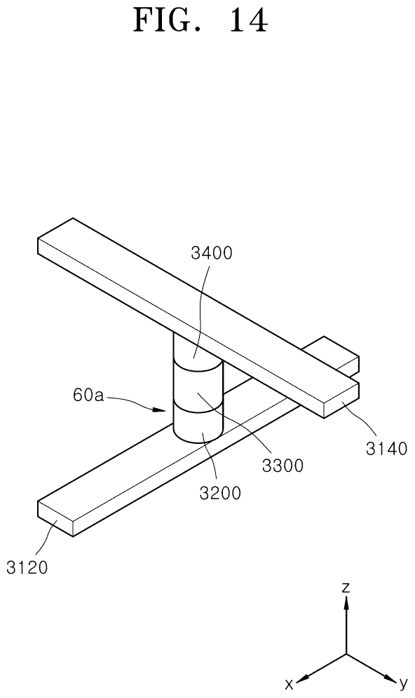

FIG. 13 is a schematic perspective view illustrating a semiconductor device according to another embodiment of the present disclosure. FIG. 14 to FIG. 17 are schematic perspective views illustrating device structures of a semiconductor device according to various embodiments of the present disclosure.

Referring to FIG. 13, a semiconductor device 6 includes a plurality of first conductive lines 3120 and a plurality of second conductive lines 3140 which are disposed on different planes. The semiconductor device 6 includes a plurality of device structures 60 disposed at positions where the first conductive lines 3120 and the second conductive lines 3140 intersect. Each of the device structures 60 includes a pillar structure electrically connected to the first conductive line 3120 and the second conductive line 3140. Although not illustrated for convenience of explanation, insulation layers may be disposed in the remaining spaces except for the regions occupied by the first conductive lines 3120, the second conductive lines 3140, and the device structures.

As illustrated in FIG. 13, the plurality of first conductive lines 3120 are arranged in the y-direction, and the plurality of second conductive lines 3140 are arranged in the x-direction. The plurality of device structures 60 are disposed to extend in the z-direction at the regions where the first conductive lines 3120 and the second conductive lines 3140 intersect. Meanwhile, in the embodiment of FIG. 13, the x-direction and the y-direction are depicted as an orthogonal coordinate system in which the x-direction and the y-direction are orthogonal to each other, but the present disclosure is not necessarily limited thereto, and various modified examples may exist as long as the condition that the x-direction and the y-direction are not parallel is satisfied. The device structures 60 form a plurality of arrays along the x-direction and the y-direction. Each of the plurality of device structures 60 forms a memory cell of the semiconductor device 6.

The first and second conductive lines 3120 and 3140 are signal lines of the semiconductor device 6 and conductive layers in the form of lines. Each of the first and second conductive lines 3120 and 3140 includes a conductive material. The conductive material may include, for example, metal, metal nitride, metal oxide, metal silicide, or a doped semiconductor material. The conductive material may include, for example, tungsten (W), aluminum (Al), copper (Cu), tantalum (Ta), titanium (Ti), gold (Au), platinum (Pt), silver (Ag), ruthenium (Ru), iridium (Ir), molybdenum (Mo), tungsten nitride, titanium nitride, tantalum nitride, doped silicon (Si), or a combination of two or more thereof.

FIG. 14 is an enlarged view that schematically illustrates a device structure according to an embodiment of the device structure 60 shown in FIG. 13. Referring to FIG. 14, a device structure 60a includes a resistance change layer 3200, an oxygen vacancy reservoir layer 3300, and a thermal confinement electrode layer 3400 that are disposed between the first conductive line 3120 and the second conductive line 3140.

The resistance change layer 3200 is disposed to contact the first conductive line 3120. The oxygen vacancy reservoir layer 3300 is disposed on the resistance change layer 3200. The thermal confinement electrode layer 3400 is disposed on the oxygen vacancy reservoir layer 3300. The thermal confinement electrode layer 3400 is disposed to contact the second conductive line 3140.

The materials and electrical characteristics of the resistance change layer 3200, the oxygen vacancy reservoir layer 3300, and the thermal confinement electrode layer 3400 may be substantially the same as the materials and electrical characteristics of the resistance change layer 1200, the oxygen vacancy reservoir layer 1300, and the thermal confinement electrode layer 1400 of the semiconductor device 4 of FIG. 7 to FIG. 9.

A set voltage or a reset voltage is applied between the first conductive line 3120 and the second conductive line 3140, and a set operation or a reset operation is performed in the device structure 60a. The thermal confinement electrode layer 3400 has a lower thermal conductivity than the adjacent second conductive line 3140, thereby helping heat generated in the resistance change layer 3200 and the oxygen vacancy reservoir layer 3300 to remain inside the device structure 60a during the set operation or the reset operation in the device structure 60a.

In this way, in the semiconductor device 6 of the embodiment of the present disclosure, the device structure 60a includes the thermal confinement electrode layer 3400, thereby improving reliability of the semiconductor device 6, such as resistance switching characteristics, data linearity, and information retention.

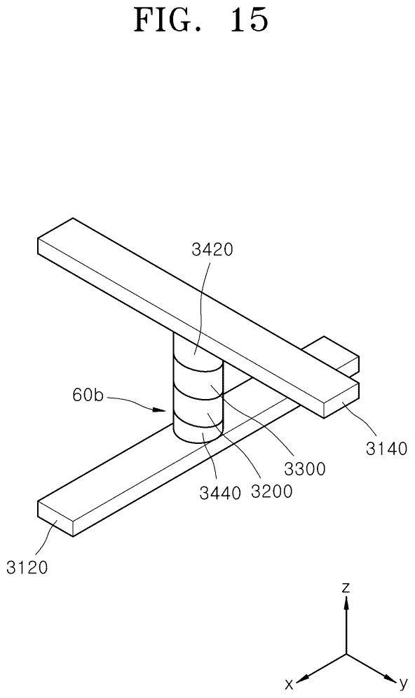

FIG. 15 is an enlarged view that schematically illustrates a device structure according to another embodiment of the device structure 60 shown in FIG. 13. Referring to FIG. 15, a device structure 60b includes a resistance change layer 3200, an oxygen vacancy reservoir layer 3300, and first and second thermal confinement electrode layers 3420 and 3440 that are disposed between a first conductive line 3120 and a second conductive line 3140. Compared to the device structure 60a of FIG. 14, the device structure 60b further includes the second thermal confinement electrode layer 3440 disposed between the first conduction line 3120 and the resistance change layer 3200.

Referring to FIG. 15, the first thermal confinement electrode layer 3420 is disposed between the oxygen vacancy reservoir layer 3300 and the second conductive line 3140. The first thermal confinement electrode layer 3420 has a configuration substantially the same as a configuration of the thermal confinement electrode layer 3400 of FIG. 14.

The second thermal confinement electrode layer 3440 may serve to inhibit heat inside the resistance change layer 3200 from being conducted to the first conductive line 3120. In addition, the second thermal confinement electrode layer 3440 may be electrically connected to the first conductive line 3120 to function as an electrode within the device structure 60b.

The second thermal confinement electrode layer 3440 may include an electrically conductive material having lower thermal conductivity than the first conductive line 3120. The second thermal confinement electrode layer 3440 includes substantially the same material as the first thermal confinement electrode layer 3420.

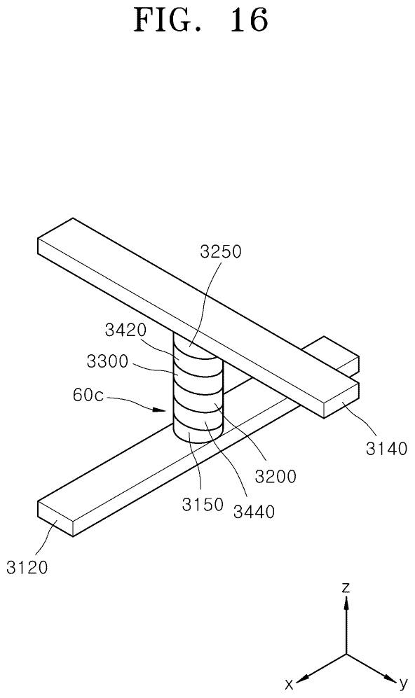

FIG. 16 is an enlarged view that schematically illustrates a device structure according to another embodiment of the device structure 60 shown in FIG. 13. Referring to FIG. 16, a device structure 60c further includes a first electrode layer 3150 and a second electrode layer 3250 that are in contact with the first conductive line 3120 and the second conductive line 3140, respectively, compared to the device structure 60b of FIG. 15.

Referring to FIG. 16, inside the device structure 60c, the first electrode layer 3150 is disposed between the first conductive line 3120 and the second thermal confinement electrode layer 3440, and the second electrode layer 3250 is disposed between the second conductive line 3140 and the first thermal confinement electrode layer 3420. The first electrode layer 3150 and the second electrode layer 3250 are electrically connected to the first conductive line 3120 and the second conductive line 3140, respectively, inside the device structure 60c.

Each of the first and second electrode layers 3150 and 3250 includes a conductive material. The conductive material includes, for example, metal, metal nitride, metal oxide, metal silicide, or a doped semiconductor material.

In some embodiments, the first and second electrode layers 3150 and 3250 may be applied to the device structure 60a of FIG. 14. In this case, the first electrode layer 3150 may be disposed between the first conductive line 3120 and the resistance change layer 3200, and the second electrode layer 3250 may be disposed between the thermal confinement electrode layer 3400 and the second conductive line 3140.

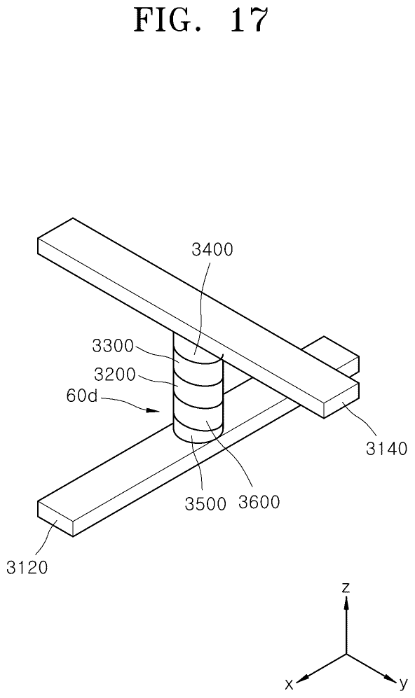

FIG. 17 is an enlarged view that schematically illustrates a device structure according to another embodiment of the device structure 60 shown in FIG. 13. Referring to FIG. 17, a device structure 60d further includes a selection device layer 3500 and an intermediate electrode layer 3600, compared to the device structure 60a of FIG. 14.

Referring to FIG. 17, the selection device layer 3500 is disposed on a first conductive line 3120. The intermediate electrode layer 3600 is disposed on the selection device layer 3500. A resistance change layer 3200 is disposed on the intermediate electrode layer 3600.

The selection device layer 3500 may be a switching layer that performs a threshold switching operation. The selection device layer 3500 may decrease a leakage current flowing in from a neighboring device structure when a cross-point array device is driven. Specifically, the selection device layer 3500 may maintain a turn-off state when a voltage or current applied to the selection device layer 3500 is below a threshold value. When the applied voltage or current reaches the threshold value, the selection device layer 3500 is turned on and outputs a current that increases non-linearly with respect to the applied voltage or current.

The selection device layer 3500 may include, for example, a metal-insulator transition (hereinafter, referred to as “MIT”) device layer, a mixed ion-electron conduction (hereinafter, referred to as “MIEC”) device layer, an ovonic threshold switch (hereinafter, referred to as “OTS”) device layer, or a tunnel insulation device layer.

The MIT device layer may include, for example, NbO₂, TiO₂, VO₂, WO₂, or the like. The MIEC device layer may include, for example, ZrO₂(Y₂O₃), Bi₂O₃—BaO, (La₂O₃)×(CeO₂)₁₋ₓ (0<x<1), or the like. The OTS device layer may include, for example, a chalcogenide-based material such as Ge₂Sb₂Te₅, As₂Te₃, As₂, As₂Se₃, or the like. The tunnel insulation device layer may include, for example, silicon oxide, silicon nitride, or the like.

The intermediate electrode layer 3600 separates the selection device layer 3500 and the resistance change layer 3200 from each other. The intermediate electrode layer 3600 includes a conductive material. The conductive material may include, for example, metal, metal nitride, metal oxide, metal silicide, or a doped semiconductor material.

In some embodiments, the selection device layer 3500 and the intermediate electrode layer 3600 may be applied to the device structure 60b of FIG. 15. As an example, the selection device layer may be disposed on the second thermal confinement electrode layer 3440. The intermediate electrode layer may be disposed on the selection device layer, and the resistance change layer 3200 may be disposed on the intermediate electrode layer. As another example, the selection device layer may be disposed on the first conductive line 3120, and the intermediate electrode layer may be disposed on the selection device layer. In addition, the second thermal confinement electrode layer 3440 may be disposed on the intermediate electrode layer.

In some embodiments, the selection device layer 3500 and the intermediate electrode layer 3600 may be applied to the device structure 60c of FIG. 16. As an example, the selection device layer may be disposed on the second thermal confinement electrode layer 3440. The intermediate electrode layer may be disposed on the selection device layer, and the resistance change layer 3200 may be disposed on the intermediate electrode layer. As another example, the selection device layer may be disposed on the first electrode layer 3150, and the intermediate electrode layer may be disposed on the selection device layer. In addition, the second thermal confinement electrode layer 3440 may be disposed on the intermediate electrode layer.

Concepts are disclosed in conjunction with various embodiments as described above. Those skilled in the art will understand that various modifications, additions, and substitutions are possible, without departing from the scope and spirit of the present disclosure. Accordingly, the embodiments disclosed in the present specification should not be considered from a restrictive standpoint but rather from an illustrative standpoint. The scope of the present disclosure is not limited to the above descriptions, and all of distinctive features within an equivalent scope should be construed as being included in the present disclosure.

What is claimed is:

1. A semiconductor device comprising:
a substrate;
an electrode structure disposed over the substrate and including interlayer insulation layers and horizontal electrode layers which are alternately disposed;
a resistance change layer disposed along a sidewall surface of a hole that penetrates the electrode structure over the substrate;
an oxygen vacancy reservoir layer disposed on the resistance change layer within the hole;
a first thermal confinement electrode layer disposed on the oxygen vacancy reservoir layer within the hole; and
a vertical electrode layer disposed on the first thermal confinement electrode layer within the hole.

2. The semiconductor device of claim 1, wherein the first thermal confinement electrode layer comprises a conductive material having lower conductivity than the vertical electrode layer.

3. The semiconductor device of claim 1, wherein the first thermal confinement electrode layer comprises metal silicon nitride.

4. The semiconductor device of claim 3, wherein the metal silicon nitride comprises at least one of tungsten silicon nitride, titanium silicon nitride, and aluminum silicon nitride.

5. The semiconductor device of claim 1, wherein the first thermal confinement electrode layer comprises an amorphous carbon layer.

6. The semiconductor device of claim 1, wherein the first thermal confinement electrode layer has a thickness of 10 Å to 100 Å.

7. The semiconductor device of claim 1, wherein the first thermal confinement electrode layer is disposed to cover the oxygen vacancy reservoir layer along the sidewall surface of the hole.

8. The semiconductor device of claim 1, further comprising a second thermal confinement electrode layer disposed between the electrode structure and the resistance change layer along the sidewall surface of the hole.

9. The semiconductor device of claim 1,
wherein the resistance change layer is configured to have a plurality of conductance values, and
wherein the plurality of conductance values are configured to be changed substantially linearly in magnitude depending on a voltage applied to the resistance change layer.

10. The semiconductor device of claim 1, wherein the resistance change layer comprises at least one selected from the group consisting of hafnium oxide, zirconium oxide, hafnium zirconium oxide, titanium oxide, and aluminum oxide.

11. The semiconductor device of claim 1, wherein the oxygen vacancy reservoir layer comprises at least one selected from the group consisting of tantalum (Ta), titanium (Ti), zirconium (Zr), vanadium (V), tungsten (W), and ruthenium (Ru).

12. The semiconductor device of claim 1,
wherein the horizontal electrode layers extend in a direction parallel to a surface of the substrate, and
wherein the vertical electrode layer extends in a direction perpendicular to the surface of the substrate.

13. A semiconductor device comprising:
a first conductive line and a second conductive line that are disposed on different planes; and
a device structure disposed in a region where the first conductive line and the second conductive line intersect,
wherein the device structure comprises a resistance change layer, an oxygen vacancy reservoir layer, and a first thermal confinement electrode layer that are sequentially disposed between the first conductive line and the second conductive line.

14. The semiconductor device of claim 13, wherein the first thermal confinement electrode layer comprises an electrically conductive material having lower thermal conductivity than the second conductive line.

15. The semiconductor device of claim 13, wherein the device structure comprises a pillar structure that is electrically connected to the first conductive line and the second conductive line.

16. The semiconductor device of claim 13, wherein the resistance change layer is disposed on the first conductive line, the oxygen vacancy reservoir layer is disposed on the resistance change layer, and the first thermal confinement electrode layer is disposed on the oxygen vacancy reservoir layer.

17. The semiconductor device of claim 16, wherein the device structure further comprises a second thermal confinement electrode layer disposed between the first conductive line and the resistance change layer.

18. The semiconductor device of claim 16, wherein the device structure further comprises:
a first electrode layer disposed between the first conductive line and the resistance change layer; and
a second electrode layer disposed between the first thermal confinement electrode layer and the second conductive line.

19. The semiconductor device of claim 16, further comprising a selection device layer disposed between the first conductive line and the resistance change layer.

20. The semiconductor device of claim 19, wherein the selection device layer comprises one of a metal-insulator transition (MIT) device layer, a mixed ion-electron conduction (MIEC) device layer, an ovonic threshold switch (OTS) device layer, and a tunnel insulation device layer.
